(19) United States
(12) Patent Application Publication
(10) Pub. No.: US 2014/0048903 A1
(43) Pub. Date: Feb. 20, 2014

(54) METHOD AND SYSTEM FOR EDGE TERMINATION IN GAN MATERIALS BY SELECTIVE AREA IMPLANTATION DOPING

(71) Applicants: Andrew Edwards, San Jose, CA (US); Hui Nie, Cupertino, CA (US); Isik Kizilyalli, San Francisco, CA (US); Dave Bour, Cupertino, CA (US)

(72) Inventors: Andrew Edwards, San Jose, CA (US); Hui Nie, Cupertino, CA (US); Isik Kizilyalli, San Francisco, CA (US); Dave Bour, Cupertino, CA (US)

(73) Assignee: AVOGY, INC., San Jose, CA (US)

(21) Appl. No.: 13/586,330

(22) Filed: Aug. 15, 2012

(51) Int. Cl. H01L 29/872; H01L 21/20

(52) U.S. Cl. 257/472; 438/478; 257/E21.09; 257/E29.338

(57) ABSTRACT

A method for fabricating edge termination structures in gallium nitride (GaN) materials includes providing an n-type GaN substrate having a first surface and a second surface, forming an n-type GaN epitaxial layer coupled to the first surface of the n-type GaN substrate, and forming one or more p-type regions in the n-type GaN epitaxial layer by using a first ion implantation. At least one of the one or more p-type regions includes an edge termination structure.

### CROSS-REFERENCES TO RELATED APPLICATIONS

The following regular U.S. patent applications are incorporated by reference into this application for all purposes:
application Ser. No. 13/270,606, filed Oct. 11, 2011, entitled “METHOD AND SYSTEM FOR FLOATING GUARD RINGS IN GAN MATERIALS”; and
application Ser. No. 13/270,625, filed Oct. 11, 2011, entitled “METHOD FOR FABRICATING A GAN MERGED PIN, SCHOTTKY (MPS) DIODE”.

### BACKGROUND OF THE INVENTION

Power electronics are widely used in a variety of applications. Power electronic devices are commonly used in circuits to modify the form of electrical energy, for example, from AC to DC or vice-versa, from one voltage level to another, or in some other way. Such devices can operate over a wide range of power levels, from milliwatts in mobile devices to hundreds of megawatts in a high voltage power transmission system. Despite the progress made in power electronics, there is a need in the art for improved electronics systems and methods of operating the same.

### SUMMARY OF THE INVENTION

The present invention relates generally to electronic devices. More specifically, the present invention relates to forming edge termination structures using III-nitride semiconductor materials. Merely by way of example, the invention has been applied to methods and systems for manufacturing guard rings for semiconductor devices using gallium-nitride (GaN) based epitaxial layers. The methods and techniques can be applied to a variety of compound semiconductor systems such as Schottky diodes, PIN diodes, vertical junction field-effect transistors (JFETs), thyristors, and other devices.

According to an embodiment of the present invention, a method for fabricating edge termination structures in gallium nitride (GaN) materials is provided. The method includes providing an n-type GaN substrate having a first surface and a second surface, forming an n-type GaN epitaxial layer coupled to the first surface of the n-type GaN substrate, and forming one or more p-type regions in the n-type GaN epitaxial layer by using a first ion implantation. At least one of the one or more p-type regions includes an edge termination structure.

According to another embodiment of the present invention, a method of fabricating an epitaxial structure is provided. The method includes providing a III-nitride substrate, forming a III-nitride epitaxial layer coupled to the III-nitride substrate, and forming at least one edge termination structure. The at least one edge termination structure is formed by forming an implantation mask on the III-nitride epitaxial layer, patterning the implantation mask to expose at least one region of the III-nitride epitaxial layer, and using ion implantation to dope the at least one exposed region of the III-nitride epitaxial layer, forming the at least one edge termination structure.

According to yet another embodiment of the present invention, a semiconductor structure includes a III-nitride substrate characterized by a certain conductivity type, a III-nitride epitaxial layer of the certain conductivity type coupled to the III-nitride substrate, and one or more doped regions in the III-nitride epitaxial layer. At least one of the one or more doped regions includes an edge termination structure.

Numerous benefits are achieved by way of the present invention over conventional techniques. For example, embodiments of the present invention enable the use vertical devices with thicker III-nitride semiconductor layers in comparison with conventional techniques, which can result in devices capable of operating at higher voltages than conventional devices. Additionally, the use of implantation doping techniques detailed herein provides enhanced doping control and design flexibility over conventional techniques, providing more control over the design of edge termination structures. These and other embodiments of the invention, along with many of its advantages and features, are described in more detail in conjunction with the text below and attached figures.

### BRIEF DESCRIPTION OF THE DRAWINGS

FIGS. 1A-1B are simplified cross-sectional diagrams of a portion of a semiconductor device, illustrating how edge termination structures improve the semiconductor device's performance, according to an embodiment of the present invention;

FIGS. 2-5 are simplified cross-sectional diagrams illustrating the fabrication of a PiN diode in gallium-nitride (GaN) with its main junction and edge termination structures formed through the implantation and activation of a p-type dopant, according to an embodiment of the present invention;

FIG. 6 is a simplified cross-sectional diagram illustrating fabrication of a PiN diode in GaN with edge termination structures formed through the implantation and activation of a p-type dopant, according to another embodiment of the present invention;

FIG. 7 is a simplified cross-sectional diagrams illustrating fabrication of a PiN diode in GaN with edge termination structures formed through the implantation and activation of a p-type dopant, according to another embodiment of the present invention;

FIG. 8 is a simplified cross-sectional diagrams illustrating fabrication of a PiN diode in GaN with edge termination structures formed through the implantation and activation of a p-type dopant, according to another embodiment of the present invention;

FIG. 9 is a simplified cross-sectional diagram illustrating fabrication of a Schottky diode in GaN with edge termination structures formed through the implantation and activation of a p-type dopant, according to another embodiment of the present invention;

FIG. 10 is a simplified cross-sectional diagrams illustrating fabrication of a merged PiN Schottky (MPS) diode in GaN with edge termination structures formed through the implantation and activation of a p-type dopant according to another embodiment of the present invention;

FIG. 11 is simplified cross-sectional diagram illustrating a vertical JFET with edge termination structures according to another embodiment of the present invention;

FIGS. 12-14 are simplified top-view illustrations showing different example embodiments of edge termination structures according to embodiments of the present invention;

FIG. 15 is a simplified flowchart illustrating a method of fabricating a PiN diode with edge termination structures formed through implantation and activation of a p-type dopant according to an embodiment of the present invention; and

FIG. 16 is a simplified flowchart illustrating a method of fabricating a Schottky diode with edge termination structures formed through the implantation and activation of a p-type dopant according to an embodiment of the present invention.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION OF THE INVENTION

Embodiments of the present invention relate to electronic devices. More specifically, the present invention relates to forming edge termination structures, such as floating guard rings or junction termination extension, to provide edge termination for semiconductor devices. Merely by way of example, the invention has been applied to methods and systems for manufacturing edge termination structures using gallium-nitride (GaN) based epitaxial layers. The methods and techniques can be applied to form a variety of types of edge termination structures that can provide edge termination to numerous types of semiconductor devices, including, but not limited to, junction field-effect transistors (JFETs), diodes, thyristors, vertical field-effect transistors, thyristors, bipolar transistors and other devices.

GaN-based electronic and optoelectronic devices are undergoing rapid development, and generally are expected to outperform competitors in silicon (Si) and silicon carbide (SiC). Desirable properties associated with GaN and related alloys and heterostructures include high bandgap energy for visible and ultraviolet light emission, favorable transport properties (e.g., high electron mobility and saturation velocity), a high breakdown field, and high thermal conductivity. In particular, electron mobility, μ, is higher than competing materials for a given background doping level, N. This provides low resistivity, ρ, because resistivity is inversely proportional to electron mobility, as provided by equation (1):

$$ρ = \frac{1}{q μ N} , \qquad ( 1 )$$

where q is the elementary charge.

Another superior property provided by GaN materials, including homoepitaxial GaN layers on bulk GaN substrates, is high critical electric field for avalanche breakdown. A high critical electric field allows a larger voltage to be supported over smaller length, L, than a material with a lower critical electric field. A smaller length for current to flow together with low resistivity give rise to a lower resistance, R, than other materials, since resistance can be determined by equation (2):

$$R = \frac{ρ L}{A} , \qquad ( 2 )$$

where A is the cross-sectional area of the channel or current path.

As described herein, semiconductor devices utilizing edge termination structures enable devices to exploit the high critical electric field provided by GaN and related alloys and heterostructures. Edge termination techniques such as field plates and guard rings provide edge termination by alleviating high fields at the edge of the semiconductor device. When properly employed, edge termination allows a semiconductor device to break down uniformly at its main junction rather than uncontrollably at its edge.

According to embodiments of the present invention, gallium nitride (GaN) epitaxy on pseudo-bulk GaN substrates is utilized to fabricate semiconductor devices not possible using conventional techniques. For example, conventional methods of growing GaN include using a foreign substrate such as silicon carbide (SiC). This can limit the thickness of a usable GaN layer grown on the foreign substrate due to differences in thermal expansion coefficients and lattice constant between the GaN layer and the foreign substrate. High defect densities at the interface between GaN and the foreign substrate further complicate attempts to create edge termination structures for various types of semiconductor devices.

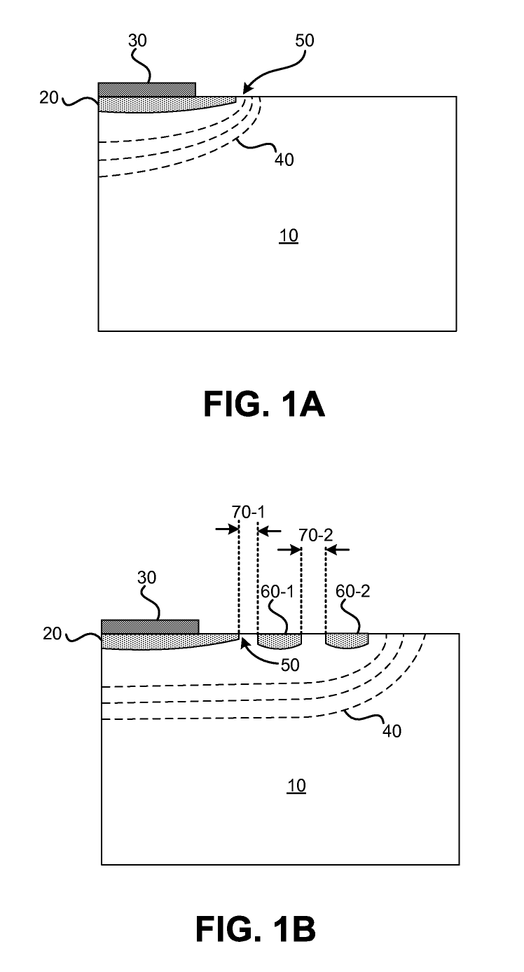

FIGS. 1A-1B are simplified cross-sectional diagrams of a portion of a semiconductor device, according to one embodiment, illustrating how the edge termination structures provided herein can be used to improve the semiconductor device's performance using edge termination. FIG. 1A illustrates a diode structure where a p-n junction is created between a p-type semiconductor layer 20 formed in an n-type semiconductor substrate 10. In this example, a metal layer 30 is also formed on the p-type semiconductor layer 20 to provide electrical connectivity to the diode.

Because the diode of FIG. 1A has no termination structures, its performance is reduced. The equipotential lines 40 (represented in FIG. 1A as dotted lines), follow the shape of the electrode which has voltage applied to it, causing field crowding near the edge 50 of the diode, since electric field is equal to the negative of the gradient in voltage. A breakdown mechanism, such as avalanche multiplication of carriers, is initiated by high electric field in a semiconductor region. This results in breakdown at a voltage that can be much less than the parallel plane breakdown voltage for the diode. This phenomenon can be especially detrimental to the operation of high-voltage semiconductor devices.

FIG. 1B illustrates how edge termination structures 60 can be used to alleviate field crowding near the edge 50 of the diode. The edge termination structures 60, which can be formed by implantation and activation of a p-type dopant such as Mg, Be, Zn, Ca, or the like are placed near the diode such that they create conducting regions that are allowed to float to voltages lower than that of the applied voltage at the main junction. The potential 40 is extended laterally beyond the edge 50 of the diode. By extending the voltage drop over a larger distance in this manner, field crowding is lessened, and the edge termination structures 60 can enable the diode to operate at a breakdown voltage much closer to its parallel plane breakdown voltage.

The number of edge termination structures 60 can vary. In some embodiments, a single edge termination structure may be sufficient. In other embodiments, as many as seven termination structures are used, and in other embodiments, as many as fifty, or more can be used. The number of termination structures is impacted by voltages at which the device terminal is biased. For example, the voltage for each termination structure can decrease with each successive termination structure such that the termination structure farthest from the semiconductor device has the lowest voltage. For example, if the p-type semiconductor layer 20 is biased at 600V, the edge termination structures 60-1 and 60-2 can be designed by their positioning, to float to 400V and 200V, respectively. Of course, voltages can vary, depending on the physical dimensions and configuration of the semiconductor device and edge termination structures 60. However, ensuring the outermost edge termination structure 60-2 has sufficiently low voltage such that the electric field at its edge is lower than the peak field at the semiconductor's main junction can help ensure the semiconductor device operates at or near its parallel plane breakdown voltage.

The spaces 70 between edge termination structures 60 can vary. According to some embodiments, the width of the spaces 70 between edge termination structures 60 can increase as the distance from the semiconductor structure increases. For example, as shown in the embodiment of FIG. 1B, the width of a first space 70-1 between the first edge termination structure 60-1 and the semiconductor structure can be smaller than a second space 70-2 between the second edge termination structure 60-2 and the first edge termination structure 60-1. The width of the spaces 70 can vary depending on application. According one embodiment, the width of edge termination structures 60, ranging from 0.2 μm to 5 μm, can be approximately the same for all edge termination structures 60, and the width of spaces 70 between edge termination structures 60 increases with increased distance from the semiconductor device, ranging anywhere from 0.2 μm to 6 μm or more. In other embodiments, other spacings are utilized as appropriate to the particular application.

Methods for the formation of edge termination structures in GaN and related alloys and heterostructures can differ in technique from those used in other semiconductors, such as Si or SiC. In particular the activation of p-type dopants introduced by ion implantation is very problematic in GaN and requires specialized techniques. The GaN surface tends to degrade, due to N dissociation, at temperatures well below that required to anneal the lattice and activate the implanted dopant. Techniques to achieve dopant activation, while protecting the surface, involve high overpressures of N in the annealing environment, capping layers, and pulsed heating, for example.

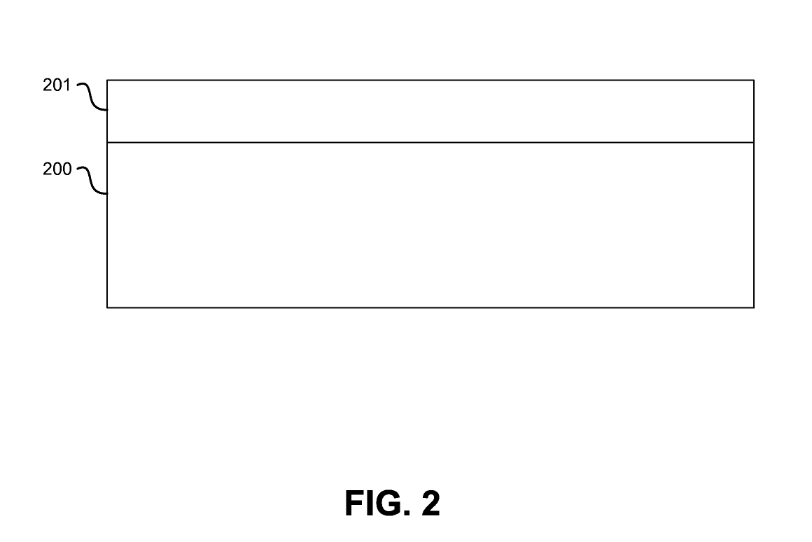

FIGS. 2-5 illustrate a process for creating a PiN diode in GaN with edge termination structures formed through selective area implantation p+ doping in an epitaxial layer. Referring to FIG. 2, a GaN epitaxial layer 201 is formed on a GaN substrate 200 having the same conductivity type. As indicated above, the GaN substrate 200 can be a pseudo-bulk GaN material on which the GaN epitaxial layer 201 is grown. Dopant concentrations (e.g., doping density) of the GaN substrate 200 can vary, depending on desired functionality. For example, a GaN substrate 200 can have an n+ conductivity type, with dopant concentrations ranging from 1×10¹⁷ cm⁻³ to 1×10¹⁹ cm⁻³. Although the GaN substrate 200 is illustrated as including a single material composition, multiple layers can be provided as part of the substrate. Moreover, adhesion, buffer, and other layers (not illustrated) can be utilized during the epitaxial growth process. One of ordinary skill in the art would recognize many variations, modifications, and alternatives.

The properties of the GaN epitaxial layer 201 can also vary, depending on desired functionality. The GaN epitaxial layer 201 can serve as a drift region for the Schottky diode, and therefore can be a relatively low-doped material. For example, the GaN epitaxial layer 201 can have an n− conductivity type, with dopant concentrations ranging from 1×10¹⁴ cm⁻³ to 1×10¹⁸ cm⁻³. Furthermore, the dopant concentration can be uniform, or can vary, for example, as a function of the thickness of the drift region.

The thickness of the GaN epitaxial layer 201 can also vary substantially, depending on the desired functionality. As discussed above, homoepitaxial growth can enable the GaN epitaxial layer 201 to be grown far thicker than layers formed using conventional methods. In general, in some embodiments, thicknesses can vary between 0.5 μm and 200 μm, for example. In other embodiments thicknesses are greater than 5 μm. Resulting parallel plane breakdown voltages for the Schottky diode can vary depending on the embodiment. Some embodiments provide for breakdown voltages of at least 100V, 300V, 600V, 1.2 kV, 1.7 kV, 3.3 kV, 5.5 kV, 13 kV, 20 kV, 35 kV, or 50 kV.

Different dopants can be used to create n- and p-type GaN epitaxial layers and structures disclosed herein. For example, n-type dopants can include silicon, oxygen, or the like. P-type dopants can include magnesium, beryllium, zinc, or the like.

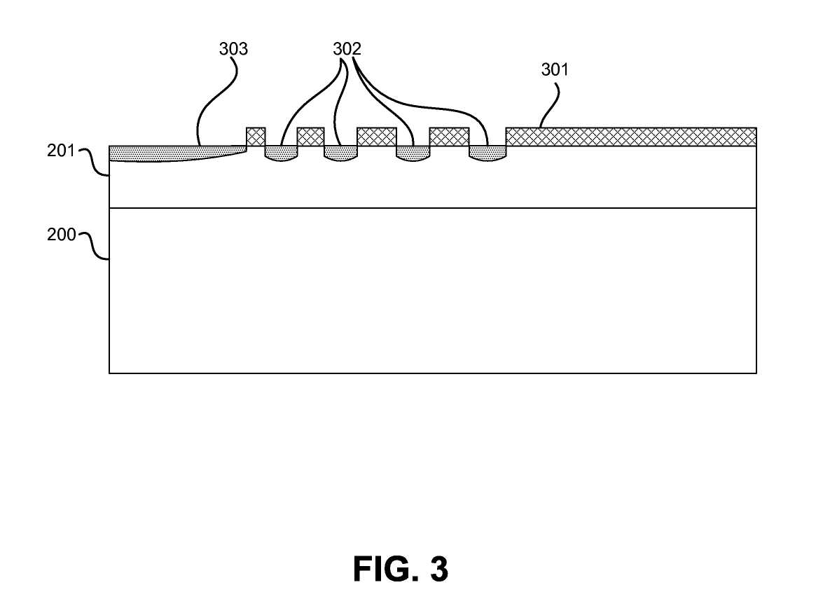

FIG. 3 illustrates the formation of edge termination structures 302 and an active region 303 of the PiN diode by ion implantation into the GaN epitaxial layer 201. A p-type dopant, such as Mg, is introduced into the GaN by ion implantation. Other p-type dopants, such as Be, Ca, or Zn, or co-implantation with another species which may or may not be a p-type dopant, such as P, are also possible. The entire wafer surface is bombarded by Mg ions, for example, accelerated to achieve energies which can range from 5 keV to 10 MeV or higher. The edge termination structures 302 are defined by a mask 301 which blocks portions of the surface where the implant is not desired and has openings where the implant is allowed to pass. The mask 301 may consist of photoresist or other materials such as Ni or Cr, for example, or some combination thereof. According to certain embodiments, the active region 303 of the PiN diode, which is also p-type, may be formed in the same ion implantation process utilized to create the edge termination structures 302. In other embodiments, an active region 303 may be formed during a separate ion implantation process. Yet other embodiments may not include forming an active region 303 with ion implantation. One of ordinary skill in the art would recognize many variations, modifications, and alternatives.

The depth and concentration of the implanted species of the edge termination structures 302 and/or active region 303 can vary, depending on the energy and dose of the implant(s). Typically multiple energies and doses will be utilized to form a layer with nearly uniform concentration to a desired depth. In some embodiments, the depth of the implant is between 0.1 μm and 5 μm. In other embodiments, the depth of the implant is between 0.3 μm and 1 μm.

The edge termination structures 302 and/or active region 303 can have a high concentration of ions introduced by implantation, for example in a range from about 1×10¹⁷ cm⁻³ to about 1×10²⁰ cm⁻³. The implantation technique causes extensive damage to the crystal lattice due the high energy bombardment of massive ions. In order for the implanted ions to become electrically active, the lattice can be repaired substantially, and a portion of the dopant ions can take substitutional sites (e.g. in place of nominally Ga or N lattice sites). The lattice repair is effected by high temperature annealing, which provides thermal energy allowing the damaged lattice structure to be altered, then reform in a lower energy state upon cooling. The required annealing temperature is typically a large percentage of the melting point of the material, which poses a problem for GaN. Well before the melting point, or even before an effective annealing temperature, N atoms tend to dissociate from the lattice near the surface, leaving behind a Ga rich surface, or in more extreme cases, Ga droplets.

One method of annealing GaN while preserving the surface quality consists of applying pulses of high temperature in a pressurized container, providing high N overpressure. A capping material is also used to protect the surface. This technique is described in U.S. Pub. No. US2012/0068188 A1, by Feigelson et al., entitled “Defects annealing and impurities activation in III-Nitride compound semiconductors,” which is incorporated by reference in its entirety.

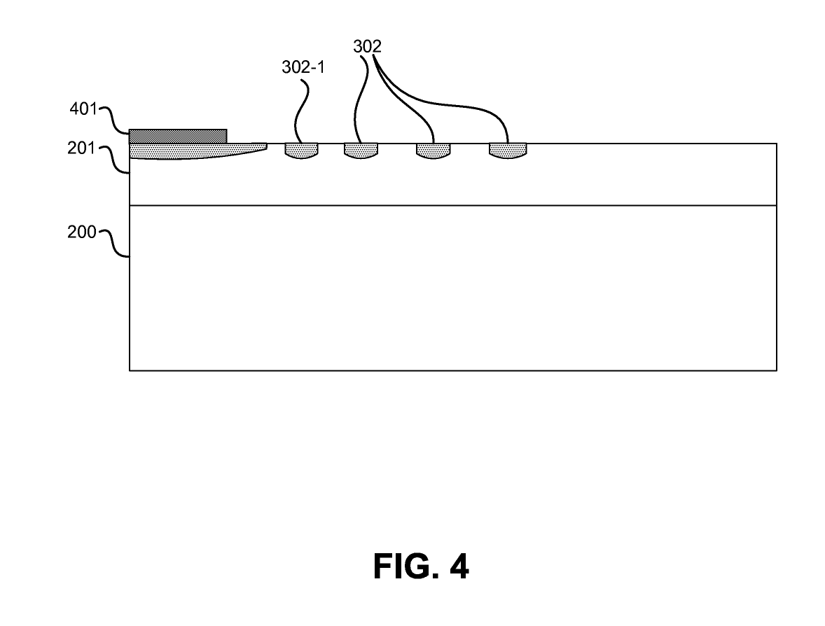

FIG. 4 illustrates the formation of a first metallic structure 401 on the GaN epitaxial layer 201. The first metallic structure 401 can be one or more layers of metal and/or alloys to create an ohmic contact with the p+ implanted GaN epitaxial layer 201. In some embodiments, the first metallic structure 401 further can overlap portions of the nearest edge termination structure 302-1. The first metallic structure 401 can be formed using a variety of techniques, including lift-off and/or deposition with subsequent etching, which can vary depending on the metals used. Metals such as Pt, Pd, or Ni, among others, can be used as an ohmic contact to p+ GaN.

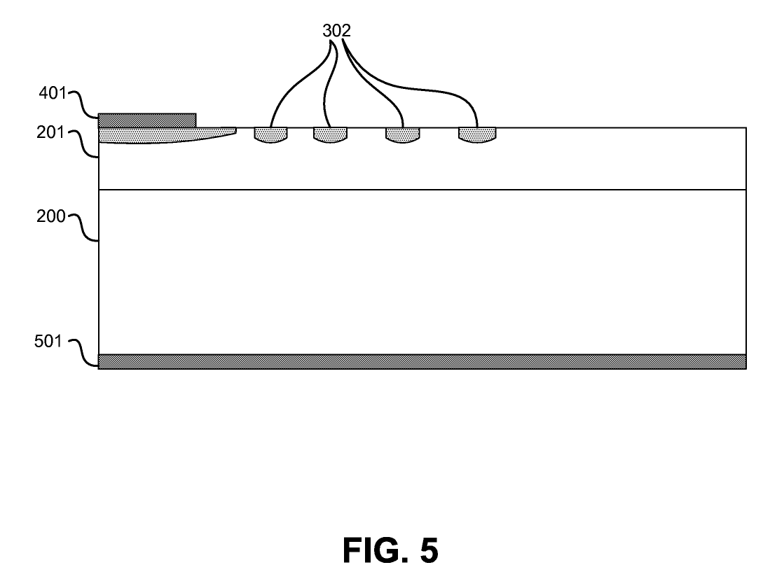

FIG. 5 illustrates the formation of a second metallic structure 501 below the GaN substrate 200. The second metallic structure 501 can be one or more layers of ohmic metal that serve as a contact for the cathode of the PiN diode. For example, the second metallic structure 501 can comprise a titanium-aluminum (Ti/Al) ohmic metal. Other metals and/or alloys can be used including, but not limited to, aluminum, nickel, gold, and the like, including combinations thereof. In some embodiments, an outermost metal of second metallic structure 501 can include gold, tantalum, tungsten, palladium, silver, or aluminum, and the like, including combinations thereof. The second metallic structure 501 can be formed using any of a variety of methods such as sputtering, evaporation, and the like.

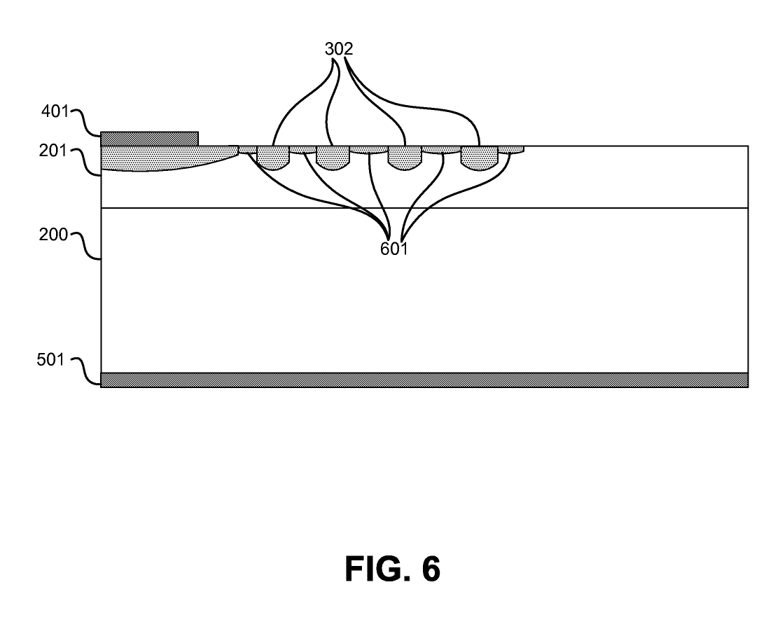

FIG. 6 shows another embodiment of a GaN semiconductor device with an implanted edge termination structure. Here, implanted regions 601 from a second implant can be used to form precisely defined resistive connections between adjacent edge termination structures 302. For example, a substantially uniform Mg concentration of approximately 5×10¹⁹ cm⁻3 may be obtained to a depth of approximately 0.5 μm by implanting at 35 keV, 140 keV, and 400 keV with doses of 2×10¹⁴ cm⁻³, 8.2×10¹⁴ cm⁻³, and 2.1×10¹⁵ cm⁻³, respectively.

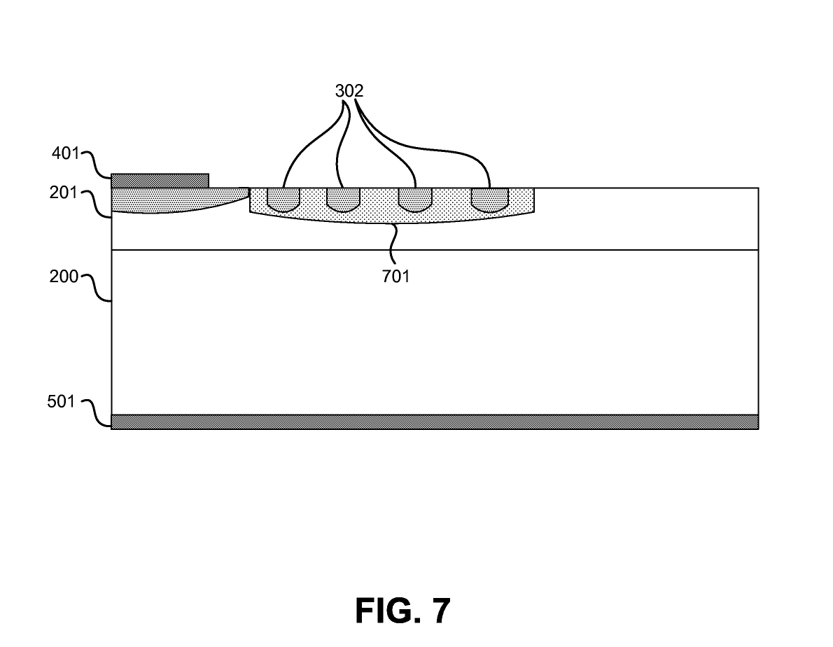

FIG. 7 shows yet another embodiment of a GaN semiconductor device with an implanted edge termination structure. Here, a second Mg implant is used to form a deep implanted region 701, creating a well that contains the edge termination structures 302 formed by the first implant.

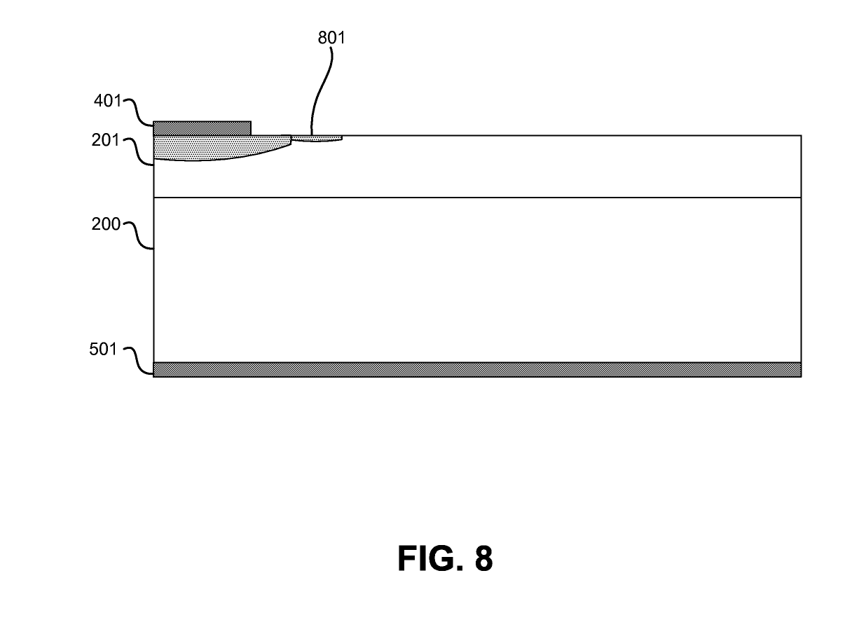

FIG. 8 shows yet another embodiment of a GaN semiconductor device with an implanted edge termination structure. In this embodiment a junction termination extension (JTE) 801 is created. The JTE can enable a more precise control of the depletion region charge near the edge of the junction, allowing for high breakdown voltages near the theoretical ideal.

Although some embodiments are discussed in terms of GaN substrates and GaN epitaxial layers, the present invention is not limited to these particular binary III-V materials and is applicable to a broader class of III-V materials, in particular III-nitride materials. Additionally, although a GaN substrate is illustrated in FIG. 2, embodiments of the present invention are not limited to GaN substrates. Other III-V materials, in particular, III-nitride materials, are included within the scope of the present invention and can be substituted not only for the illustrated GaN substrate, but also for other GaN-based layers and structures described herein. As examples, binary III-V (e.g., III-nitride) materials, ternary III-V (e.g., III-nitride) materials such as InGaN and AlGaN, quaternary III-nitride materials, such as AlInGaN, doped versions of these materials, and the like are included within the scope of the present invention.

The fabrication processes illustrated in FIGS. 2-8, and other figures herein below, utilize process flows in which an n-type drift layer is grown using an n-type substrate. However, the present invention is not limited to this particular configuration. In other embodiments, substrates with p-type doping are utilized. Additionally, embodiments can use materials having an opposite conductivity type to provide devices with different functionality. Thus, although some examples relate to the growth of n-type GaN epitaxial layer(s) doped with silicon, in other embodiments the techniques described herein are applicable to the growth of highly or lightly doped material, p-type material, material doped with dopants in addition to or other than silicon such as Mg, Ca, Be, Ge, Se, S, O, Te, and the like. In some embodiments, the doped regions formed by ion implantation could be n-type, achieved by implantation and activation of dopants such as Si, O, or the like. The substrates discussed herein can include a single material system or multiple material systems including composite structures of multiple layers. One of ordinary skill in the art would recognize many variations, modifications, and alternatives.

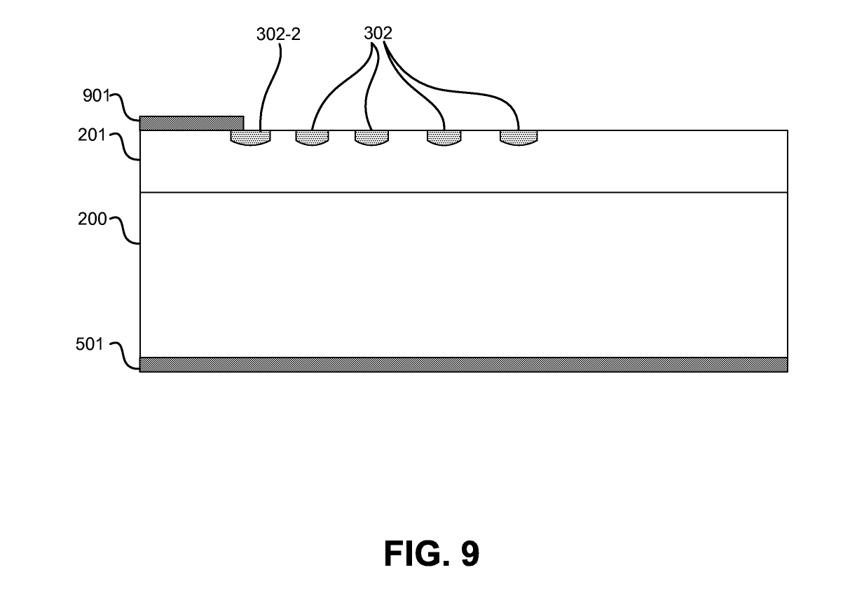

FIG. 9, illustrates the creation of a Schottky diode in GaN using ion implantation for edge termination, according to one embodiment. The process flow is similar to the PiN diode discussed above. Here, however, a Schottky metal 901 is formed on the GaN epitaxial layer 201 to create a Schottky barrier, which is protected from p-type implantation. Even so, all variations of edge termination described with the PiN diode are still realizable with this structure. Metals with a large workfunction such as Pt, Pd, and Ni, among others can be utilized in the Schottky metal 901. In some embodiments, as shown in FIG. 9, the Schottky metal can overlap with a first edge termination structure 302-2.

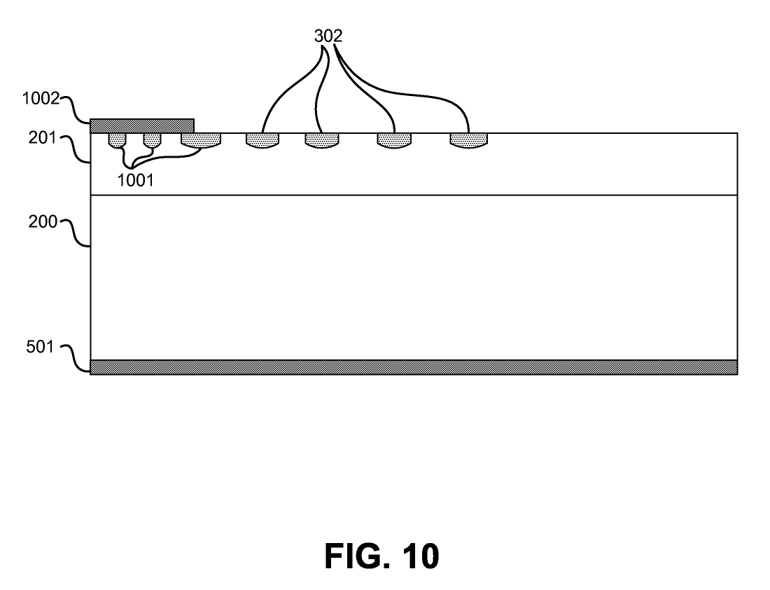

FIG. 10 illustrates yet another embodiment where ion implantation is used in GaN for edge termination. In this embodiment, implantation is also used to form the p-type regions 1001 of a merged PiN/Schottky (MPS) diode, which can be formed simultaneously with or separately from, the edge termination structures 302. This embodiment can utilize a process flow similar to that of the PiN diode discussed previously. Here, however, portions of the main junction are protected from p+ implantation. Additionally in this embodiment, a metal contact 1002 is used that is capable of forming an ohmic contact to p+ GaN while simultaneously forming a Schottky barrier to n− GaN. Again, metals with a large workfunction, such as Pt, Pd, and Ni, among others, can be utilized in the metal contact 1002.

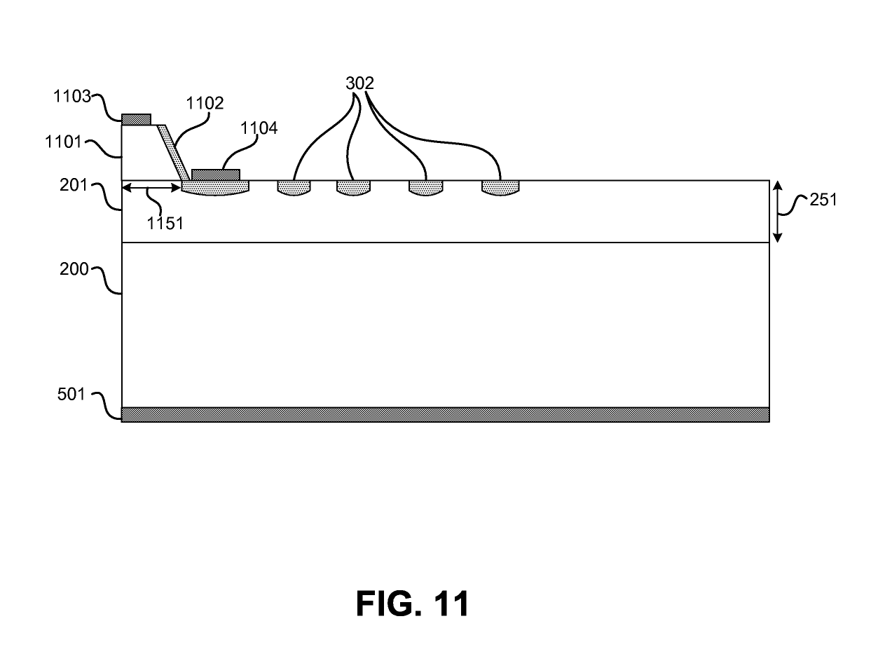

FIG. 11 is a simplified cross section of a portion of a vertical JFET with edge termination structures 302 that can be formed using ion implantation, as described herein. Similar to the structures discussed previously, the vertical JFET can include a GaN substrate 200, GaN epitaxial layer 201, and second metallic structure 501. Here, the second metallic structure 501 can function as a drain contact of the vertical JFET. Additionally, the JFET can include a channel region 1101, which can be formed through epitaxial regrowth and have a low dopant concentration similar to the GaN epitaxial layer 201, having the same conductivity type. Gate region 1102 can be formed by ion implantation, which could be formed simultaneously with or separately from implantation formation of the edge termination structures 302, and have an opposite conductivity type as the GaN epitaxial layer 201. Finally, ohmic metal contacts 1104 and 1103 can provide gate and source contacts, respectively.

In some embodiments of the ion implanted vertical JFET, the GaN substrate 200 can have an n+ conductivity type with dopant concentrations ranging from 1×10¹⁷ cm⁻³ to 1×10¹⁹ cm⁻³, and the GaN epitaxial layer 201 can have a n− conductivity type, with dopant concentrations ranging from 1×10¹⁴ cm⁻³ to 1×10¹⁸ cm⁻³. The thickness 251 of the GaN epitaxial layer 201 can be anywhere from 0.5 μm and 100 μm or over 100 μm, depending on desired functionality and breakdown voltage. The channel region 1101, which can have a n− conductivity type with a dopant concentration similar to the GaN epitaxial layer 201, can be anywhere from between 0.25 μm and 10 μm thick, and the width 1151 of the channel region 1101 for a normally-off vertical JFET can be between 0.5 μm and 10 μm. For a normally-on vertical JFET, the width 1151 of the channel region 1101 can be greater. (Note that, because FIG. 11 shows only a portion of the vertical JFET the channel may actually be wider than as indicated in FIG. 11.) The gate regions 1102 and the edge termination structures 302 can be from 0.1 μm and 5 μm thick and have a p+ conductivity type with dopant concentrations in a range from about 5×10¹⁷ cm⁻³ to about 1×10¹⁹ cm⁻³.

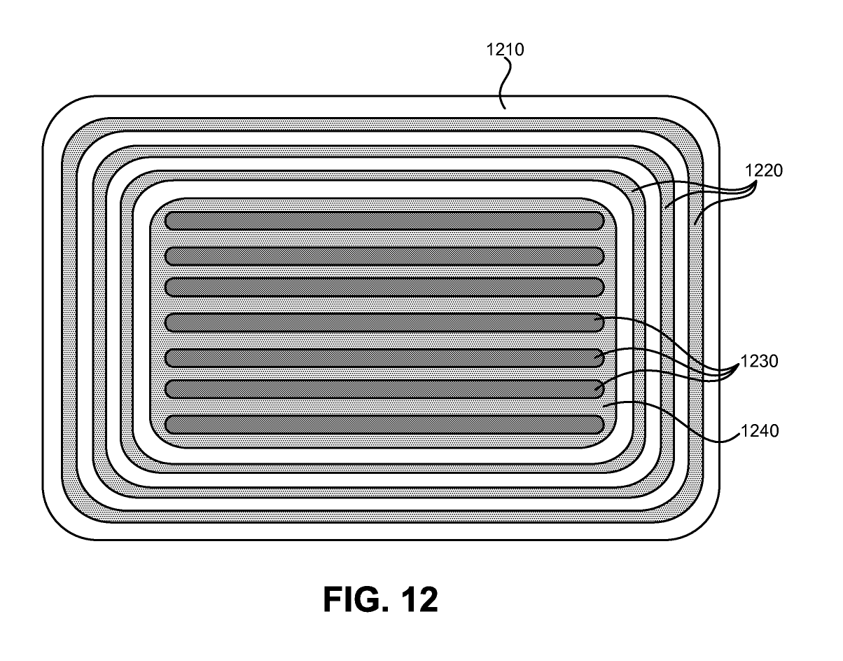

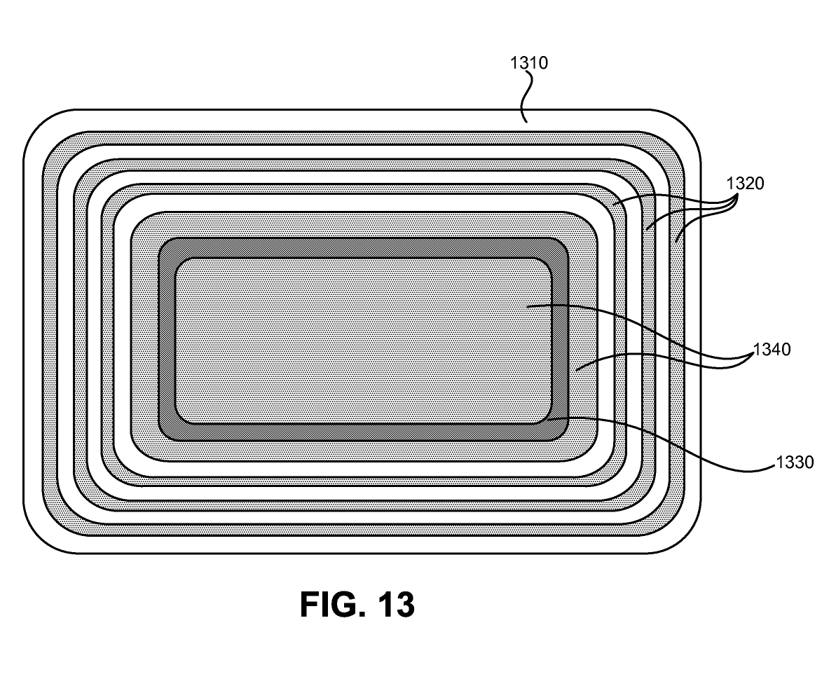

As demonstrated above, the edge termination structures described herein can provide edge termination to a variety of types of semiconductor devices. FIGS. 12-13 are simplified top-view illustrations that provide some example embodiments.

FIG. 12 illustrates an embodiment of a transistor structure with edge termination provided by three guard rings 1220. In this embodiment, the guard rings 1220 and gate structure 1240 can be made of a p+ implant into a drift region 1210 comprising an—GaN epitaxial layer. Multiple source contacts 1230 can be formed from an ohmic metal disposed on n− GaN epitaxial channel regions located between the gates.

FIG. 13 illustrates another embodiment of a transistor structure with edge termination provided by three guard rings 1320. Similar to the embodiment shown in FIG. 12, the guard rings 1320 and gate structure 1340 can be made of a p+ implant in a drift region 1310 comprising n− GaN epitaxial layer. A source contact 1330 can be formed from an ohmic metal disposed on n− GaN epitaxial channel region located between the gates formed from the gate structure 1340.

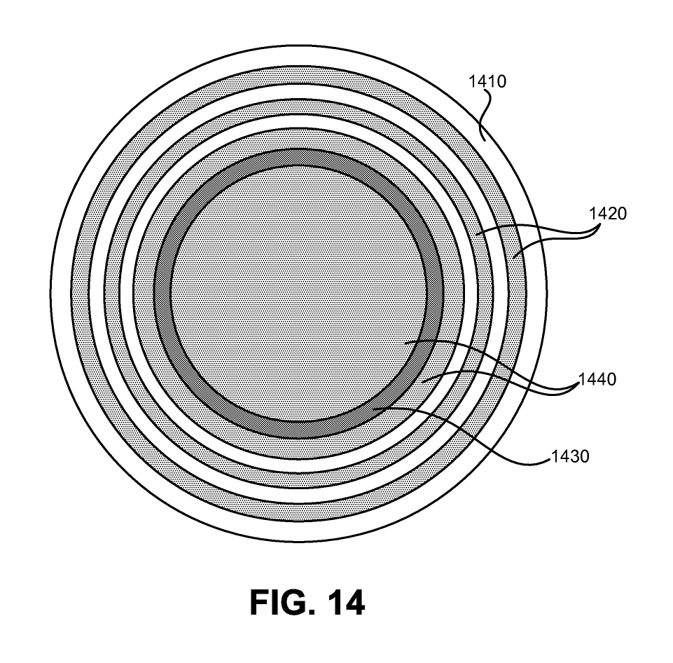

FIG. 14 illustrates yet another embodiment of a transistor structure similar to the embodiment shown in FIG. 13, illustrating how edge termination structures, such as guard rings 1420, can be shaped differently to accommodate differently-shaped semiconductor structures. Again, guard rings 1420 and gate structure 1440 can be made of a p+ implant into a drift region 1410 comprising n− GaN epitaxial layer. A source contact 1430 can be formed from an ohmic metal disposed on n− GaN epitaxial channel region located between the gates formed from the gate structure 1440.

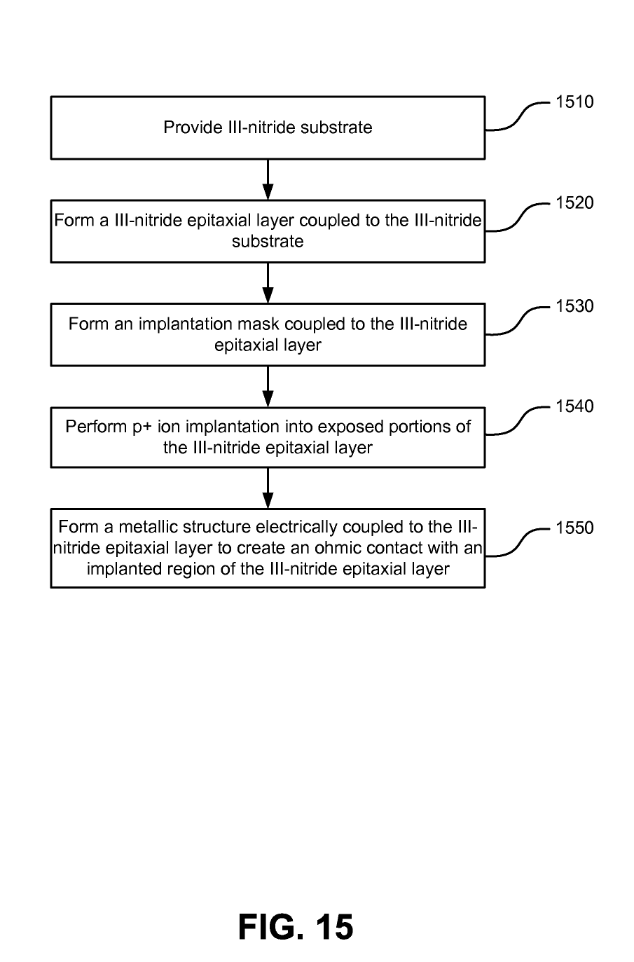

FIG. 15 is a simplified flowchart illustrating a method of fabricating a PiN diode with edge termination structures in a III-nitride material, according to an embodiment of the present invention. Referring to FIG. 15, a III-nitride substrate is provided (1510), which can be characterized by a first conductivity type and a first dopant concentration. In an embodiment, the III-nitride is a GaN substrate with n+ conductivity type. The method also includes forming a III-nitride epitaxial layer (e.g., an n-type GaN epitaxial layer) coupled to the III-nitride substrate (1520). The III-nitride substrate and III-nitride epitaxial layer are characterized by a first conductivity type, for example n-type conductivity, and the III-nitride epitaxial layer is characterized by a second dopant concentration less than the first dopant concentration. Here, the first III-nitride epitaxial layer can be an intrinsic or very lightly doped layer to function as the intrinsic region of the PIN diode. Using the homoepitaxy techniques described herein, the thickness of the III-nitride epitaxial layer can be thicker than thicknesses available using conventional techniques, for example, between about 3 μm and about 100 μm.

The method also includes forming an implantation mask coupled to the III-nitride epitaxial layer (1530) and performing a p+ ion implantation into exposed portions of the III-nitride epitaxial layer (1540). As illustrated in FIGS. 12-14 and discussed elsewhere herein, any number between one and seven or fifty or more edge termination structures can be formed to provide edge termination for the PiN diode. Thus, the implantation mask and subsequent implantation regions can be patterned in any of a variety of ways, according to desired physical characteristics of the PiN diode and other considerations.

Additionally, the method includes forming a metallic structure electrically coupled to the III-nitride epitaxial layer (1550) to create an ohmic contact between the metallic structure and the III-nitride epitaxial layer, which forms the drift layer. Moreover, as illustrated in FIG. 7, a backside ohmic metal can formed on a surface of the III-nitride substrate opposing a surface of the III-nitride substrate coupled with the III-nitride epitaxial layer, providing a cathode for the PiN diode. The various epitaxial layers used to form the PiN diode and edge termination structures do not have to be uniform in dopant concentration as a function of thickness, but may utilize varying doping profiles as appropriate to the particular application.

It should be appreciated that the specific steps illustrated in FIG. 15 provide a particular method of fabricating a PiN diode with edge termination structures according to an embodiment of the present invention. Other sequences of steps may also be performed according to alternative embodiments. For example, alternative embodiments of the present invention may perform the steps outlined above in a different order. Moreover, the individual steps illustrated in FIG. 15 may include multiple sub-steps that may be performed in various sequences as appropriate to the individual step. Furthermore, additional steps may be added or removed depending on the particular applications. One of ordinary skill in the art would recognize many variations, modifications, and alternatives.

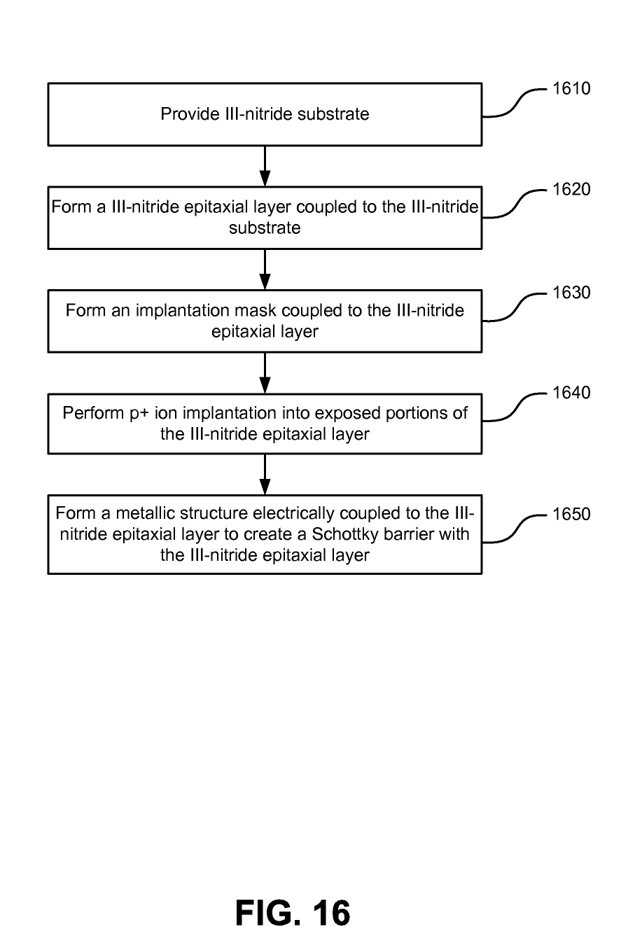

FIG. 16 is a simplified flowchart illustrating a method of fabricating a Schottky diode with edge termination structures in a III-nitride material, according to an embodiment of the present invention. Similar to the method illustrated in FIG. 15, a III-nitride substrate is provided (1610), which can have a first conductivity type and a first dopant concentration. The method also includes forming a III-nitride epitaxial layer (e.g., an n-type GaN epitaxial layer) coupled to the III-nitride substrate (1620).

The method further includes selective area doping by forming an implantation mask coupled to the III-nitride epitaxial layer (1630) and performing an ion implantation into the first III-nitride epitaxial layer (1640). The implant(s) form a p+ region at the edge of the Schottky metal, which essentially converts the edge of the Schottky diode into a PN junction and links it to the edge termination structures, also created by implantation.

The method includes forming a metallic structure electrically coupled to the device structure (1650) to create a Schottky barrier to an un-implanted portion of the III-nitride epitaxial layer. Moreover, similar to the method for creating the PiN diode, the method can include forming a backside ohmic metal coupled to the III-nitride substrate. The various epitaxial layers used to form the PIN diode and edge termination structures do not have to be uniform in dopant concentration as a function of thickness, but may utilize varying doping profiles as appropriate to the particular application.

It should be appreciated that the specific steps illustrated in FIG. 16 provide a particular method of fabricating a Schottky diode with edge termination structures according to an embodiment of the present invention. Other sequences of steps may also be performed according to alternative embodiments. For example, alternative embodiments of the present invention may perform the steps outlined above in a different order. Moreover, the individual steps illustrated in FIG. 16 may include multiple sub-steps that may be performed in various sequences as appropriate to the individual step. Furthermore, additional steps may be added or removed depending on the particular applications. One of ordinary skill in the art would recognize many variations, modifications, and alternatives.

One of ordinary skill in the art would recognize many variations, modifications, and alternatives to the examples provided herein. As illustrated herein, edge termination structures can be provided in any of a variety of shapes and forms, depending on physical features of the semiconductor device for which the edge termination structures provide edge termination. For instance, in certain embodiments, edge termination structures may not circumscribe the semiconductor device. Additionally or alternatively, conductivity types of the examples provided herein can be reversed (e.g., replacing an n-type semiconductor material with a p-type material, and vice versa), depending on desired functionality. Other variations, alterations, modifications, and substitutions are contemplated.

It is also understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A method for fabricating edge termination structures in gallium nitride (GaN) materials, the method comprising:
providing an n-type GaN substrate having a first surface and a second surface;
forming an n-type GaN epitaxial layer coupled to the first surface of the n-type GaN substrate; and
forming one or more p-type regions in the n-type GaN epitaxial layer by using a first ion implantation, wherein at least one of the one or more p-type regions comprises an edge termination structure.

2. The method of claim 1 further comprising forming and patterning an implantation mask before using the first ion implantation to form the one or more p-type regions.

3. The method of claim 1 further comprising forming a metallic structure electrically coupled to the n-type GaN epitaxial layer to create a Schottky contact.

4. The method of claim 1 wherein the one or more p-type regions comprise a plurality of edge termination structures, the method further comprising using a second ion implantation to form at least one additional p-type region that provides a resistive electrical connection between at least two of the plurality of edge termination structures.

5. The method of claim 1 wherein one of the one or more p-type regions in the n-type GaN epitaxial layer comprises an active region of a semiconductor device, the method further comprising forming a metallic structure electrically coupled to the active region of the semiconductor device.

6. The method of claim 1 further comprising forming a metallic structure coupled to the second surface of the n-type GaN substrate.

7. The method of claim 1 further comprising using a second ion implantation to form an additional p-type region that contains the edge termination structure.

8. A method of fabricating an epitaxial structure, the method comprising:
providing a III-nitride substrate;
forming a III-nitride epitaxial layer coupled to the III-nitride substrate; and
forming at least one edge termination structure by:
forming an implantation mask on the III-nitride epitaxial layer;
patterning the implantation mask to expose at least one region of the III-nitride epitaxial layer; and
using ion implantation to dope the at least one exposed region of the III-nitride epitaxial layer, forming the at least one edge termination structure.

9. The method of claim 8 further comprising forming a metallic structure coupled to the III-nitride epitaxial layer to create a Schottky contact.

10. The method of claim 8 wherein the ion implantation is used to form at least one active region of a semiconductor device.

11. The method of claim 10 wherein the at least one edge termination structure comprises a junction termination extension (JTE) of the at least one active region of the semiconductor device.

12. The method of claim 10 wherein a plurality of active regions are formed, the plurality of active regions comprising active regions of a merged PiN/Schottky (MPS) diode.

13. The method of claim 8 further comprising annealing the at least one edge termination structure in a nitrogen overpressure.

14. The method of claim 8 wherein the at least one edge termination structure circumscribes a semiconductor device.

15. The method of claim 8 wherein forming the at least one edge termination structure comprises forming three or more edge termination structures with predetermined spaces between each of the three or more edge termination structures, wherein:
a first spacing of the predetermined spaces is located closer to a semiconductor device than a second spacing of the predetermined spaces; and
a width of the first spacing is smaller than a width of the second spacing.

16. A semiconductor structure comprising:
a III-nitride substrate characterized by a certain conductivity type;
a III-nitride epitaxial layer of the certain conductivity type coupled to the III-nitride substrate; and
one or more doped regions in the III-nitride epitaxial layer, wherein at least one of the one or more doped regions comprises an edge termination structure.

17. The semiconductor structure of claim 16 wherein the one or more doped regions comprise magnesium as a dopant.

18. The semiconductor structure of claim 16 further comprising a Schottky contact formed from a metallic structure coupled to a portion of the III-nitride epitaxial layer.

19. The semiconductor structure of claim 16 wherein one of the one or more doped regions in the III-nitride epitaxial layer forms an active region of a semiconductor device.

20. The semiconductor structure of claim 19 further comprising an Ohmic contact formed from a metallic structure coupled to the active region.
